(19) United States
(12) Patent Application Publication
(10) Pub. No.: US 2014/0192598 A1
(43) Pub. Date: Jul. 10, 2014

(54) SEMICONDUCTOR MEMORY DEVICE

(71) Applicant: KABUSHIKI KAISHA TOSHIBA, Tokyo (JP)

(72) Inventors: Dong HE, Yokohama-shi (JP); Katsuaki ISOBE, Yokohama-shi (JP)

(21) Appl. No.: 14/205,061

(22) Filed: Mar. 11, 2014

Related U.S. Application Data
(63) Continuation-in-part of application No. 13/840,689, filed on Mar. 15, 2013, now abandoned.

(30) Foreign Application Priority Data
Jun. 4, 2012 (JP) 2012-127176

(51) Int. Cl. G11C 16/06

(52) U.S. Cl. CPC G11C 16/06
USPC 365/185.17

(57) ABSTRACT

According to one embodiment, a semiconductor memory device includes first hookup transistors connected to word lines, a first dummy hookup transistor connected to first dummy word line, and a second dummy hookup transistor connected to second dummy word line. A group of hookup transistors formed by the first hookup transistors, the first dummy hookup transistor, and the second dummy hookup transistor is aligned on either of one row and rows. The first dummy hookup transistor and the second dummy hookup transistor are arranged at least at one end of the group of hookup transistors.

### CROSS-REFERENCE TO RELATED APPLICATIONS

This application is a Continuation-in-Part Application of U.S. patent application Ser. No. 13/840,689, filed Mar. 15, 2013 and based upon and claiming the benefit of priority from Japanese Patent Application No. 2012-127176, filed Jun. 4, 2012; the entire contents of which are incorporated herein by reference.

### FIELD

Embodiments described herein relate generally to a semiconductor memory device.

### BACKGROUND

A NAND flash memory is known as a kind of electrically programmable nonvolatile semiconductor memory devices. In this NAND flash memory, a word line is connected to the control gate of a memory cell, and a row decoder is connected to the word line.

The row decoder includes, for example, a plurality of hookup transistors for driving a plurality of word lines. In the layout of a plurality of hookup transistors, hookup transistors formed at the ends of a region where a group of hookup transistors is arranged, and those formed inside the region may have nonuniform characteristics, that is, large variations in characteristics. As the variations in characteristics of the hookup transistors increase, it becomes more difficult to accurately perform write, read, and erase operations.

### BRIEF DESCRIPTION OF THE DRAWINGS

FIG. 1 is a block diagram of a semiconductor memory device according to the first embodiment;

FIG. 2 is a circuit diagram of a memory cell array;

FIG. 3 is a circuit diagram of a hookup circuit;

FIG. 4 is a layout diagram of the hookup circuit;

FIG. 5 is a layout diagram of a hookup circuit according to the second embodiment;

FIG. 6 is a layout diagram of a hookup circuit according to a modification;

FIG. 7 is a layout diagram of a hookup circuit according to another modification;

FIG. 8 is a layout diagram of a hookup circuit according to the third embodiment;

FIG. 9 is a circuit diagram of a hookup circuit according to the fourth embodiment;

FIG. 10 is a layout diagram of the hookup circuit according to the fourth embodiment;

FIG. 11 is a layout diagram of a hookup circuit according to the fifth embodiment;

FIG. 12 is a layout diagram of a hookup circuit according to the sixth embodiment;

FIG. 13 is a layout diagram of a hookup circuit according to the seventh embodiment;

FIG. 14 is a layout diagram of a hookup circuit according to a modification;

FIG. 15 is a circuit diagram of a hookup circuit according to the eighth embodiment;

FIG. 16 is a layout diagram of the hookup circuit according to the eighth embodiment;

FIG. 17 is a layout diagram of a hookup circuit according to the ninth embodiment;

FIG. 18 is a layout diagram of a hookup circuit according to a modification;

FIG. 19 is a layout diagram of a hookup circuit according to the tenth embodiment;

FIG. 20 is a layout diagram of a hookup circuit according to the twelfth embodiment;

FIG. 21 is a layout diagram of a hookup circuit according to the thirteenth embodiment; and

FIG. 22 is a layout diagram of a hookup circuit according to the fourteenth embodiment.

### DETAILED DESCRIPTION

In general, according to one embodiment, there is provided a semiconductor memory device comprising:

a memory cell array including memory strings, each of the memory strings including a first select transistor, a first dummy cell, memory cells, a second dummy cell, and a second select transistor connected in series, the first dummy cell being arranged between the first select transistor and the memory cells, the second dummy cell being arranged between the memory cells and the second select transistor;

word lines connected to the memory cells;

a first dummy word line connected to the first dummy cell;

a second dummy word line connected to the second dummy cell; and

a row decoder configured to drive the word lines, the first dummy word line, and the second dummy word line,

the row decoder comprising first hookup transistors connected to the word lines, a first dummy hookup transistor connected to the first dummy word line, and a second dummy hookup transistor connected to the second dummy word line,

wherein a group of hookup transistors formed by the first hookup transistors, the first dummy hookup transistor, and the second dummy hookup transistor is aligned on either of one row and rows, and

the first dummy hookup transistor and the second dummy hookup transistor are arranged at least at one end of the group of hookup transistors.

The embodiments will be described hereinafter with reference to the accompanying drawings. In the description which follows, the same or functionally equivalent elements are denoted by the same reference numerals, to thereby simplify the description.

### First Embodiment

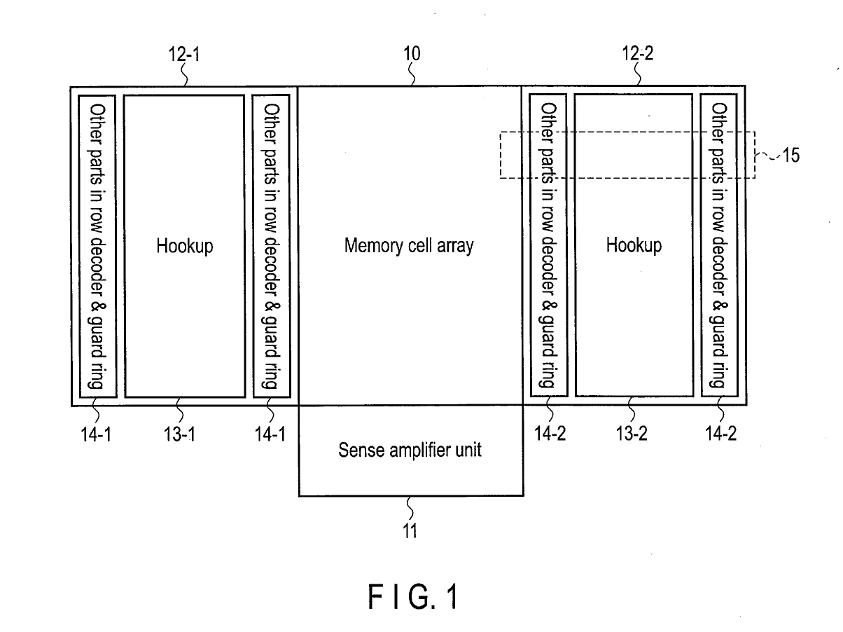

In an example in this embodiment, a semiconductor memory device will be described by taking an electrically programmable NAND flash memory as a nonvolatile memory. FIG. 1 is a block diagram of a semiconductor memory device according to the first embodiment.

The semiconductor memory device includes a memory cell array 10, a sense amplifier unit 11, and row decoder units 12-1 and 12-2.

The memory cell array 10 is configured by arranging, in a matrix, memory cell transistors (memory cells) capable of electrically programming data. A plurality of bit lines, a plurality of word lines, and a source line are arranged in the memory cell array 10 to control the voltages of the memory cell transistors. Each memory cell transistor is arranged in the intersection region between the bit line and the word line.

A plurality of sense amplifiers are arranged in the sense amplifier unit 11. Each sense amplifier is connected to one or a plurality of bit lines, and controls the voltage of the bit line during reading, writing, and erasing. Also, each sense amplifier detects data from the bit line during a read, and applies a voltage corresponding to data to be written to the bit line during a write.

Row decoder units 12-1 and 12-2 are arranged on the two sides of the memory cell array 10. As will be described later, the memory cell array 10 includes a plurality of blocks, and, for example, odd-numbered blocks of all the blocks in the memory cell array 10 are connected to row decoder unit 12-1, while even-numbered blocks of all the blocks in the memory cell array 10 are connected to row decoder unit 12-2. Row decoder units 12-1 and 12-2 are connected to the plurality of word lines.

Row decoder units 12-1 and 12-2 include hookup circuits 13-1 and 13-2, respectively. Each of hookup circuits 13-1 and 13-2 includes a plurality of hookup transistors provided in correspondence with the plurality of word lines. Each hookup transistor has a function of transferring a given voltage to the word line in synchronism with reading, writing, and erasing. Also, row decoder units 12-1 and 12-2 respectively include circuits other than hookup circuits 13-1 and 13-2, and guard rings 14-1 and 14-2. Other circuits (to be referred to as “peripheral circuits” hereinafter) in row decoder units 12-1 and 12-2 include, for example, a driver and an address decoder which decodes a row address. The peripheral circuit and guard ring 14-1 are arranged on the two sides of hookup circuit 13-1. The peripheral circuit and guard ring 14-2 are arranged on the two sides of hookup circuit 13-2. Note that in the following description, row decoder units 12-1 and 12-2 will be generically referred to as row decoder units 12 unless they need to be particularly distinguished from each other, and hookup circuits 13-1 and 13-2 will also generically be referred to as hookup circuits 13 unless they need to be particularly distinguished from each other.

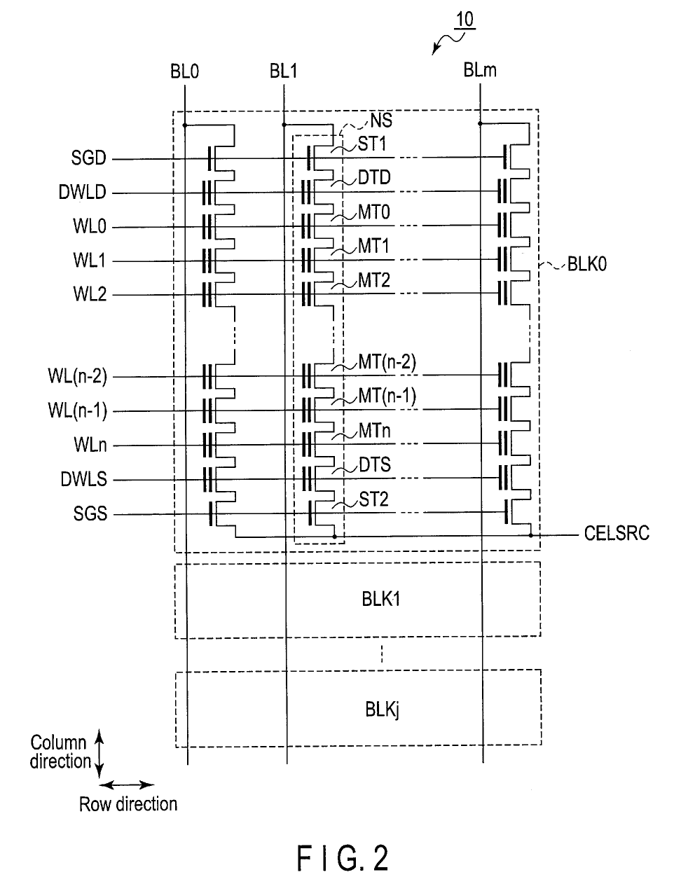

FIG. 2 is a circuit diagram of the memory cell array 10. The row direction will sometimes be referred to as a “row” hereinafter, and the column direction will sometimes be referred to as a “column” hereinafter. The memory cell array 10 includes (j+1) blocks BLK0 to BLKj (j is an integer of zero or more). Each block BLK is the unit of an erase. Each block BLK includes a plurality of NAND strings NS. Each NAND string NS includes (n+1) memory cell transistors MT0 to MTn (n is an integer of zero or more), two dummy cell transistors (dummy cells) DTD and DTS, and two select gate transistors ST1 and ST2. An N-channel metal oxide semiconductor field effect transistor (MOSFET), for example, is used as each of select gate transistors ST1 and ST2.

A memory cell transistor MT has a stacked gate structure including a charge storage layer (for example, a floating gate electrode) formed on a gate insulating film on a semiconductor substrate (well), and a control gate electrode formed on an intergate insulating film on the charge storage layer. Note that a plurality of charge storage layers may be arranged. The memory cell transistor MT can store data of any number of bits upon a change in threshold voltage corresponding to the number of electrons charged into the charge storage layer. The current paths of memory cell transistors MT adjacent in the NAND string NS form a series circuit.

The current path of dummy cell transistor DTD is connected in series between memory cell transistor MT0 and select gate transistor ST1 closest to the drain in the NAND string NS. The current path of dummy cell transistor DTS is connected in series between memory cell transistor MTn and select gate transistor ST2 closest to the source in the NAND string NS. Dummy cell transistors DTD and DTS have the same structure as the memory cell transistor MT, but are not used to store data.

Dummy cell transistor DTD is provided to prevent degradation in characteristics of memory cell transistor MT0 closest to the drain in the NAND string NS. If no dummy cell transistor DTD is used, memory cell transistor MT0 is connected to select gate transistor ST1, but under such a condition, the environment of memory cell transistor MT0 is different from those of memory cell transistors MT1 to MT(n−1), so the characteristics of memory cell transistor MT0 are inferior to those of memory cell transistors MT1 to MT(n−1). To avoid such a subject, dummy cell transistor DTD is arranged in the NAND string NS. Similarly, dummy cell transistor DTS is provided to prevent degradation in characteristics of memory cell transistor MTn closest to the source in the NAND string NS.

The control gate electrodes of memory cell transistors MT on the same row are commonly connected to one word line WL running in the row direction. The control gate electrodes of dummy cell transistors DTD or DTS on the same row are commonly connected to a dummy word line DWLD or DWLS running in the row direction. The gate electrodes of select gate transistors ST1 or ST2 on the same row are commonly connected to a select gate line SGD or SGS running in the row direction. The drain of select gate transistor ST1 is connected to a bit line BL running in the column direction. The source of select gate transistor ST2 is connected to a source line CELSRC.

A plurality of memory cell transistors MT connected to the same word line WL form a page. Data are collectively written to and read from the memory cell transistors MT in one page. Also, the memory cell array 10 is configured to collectively erase data of a plurality of pages, and the unit of erasure is the block BLK.

The bit line BL commonly connects the drains of select gate transistors ST1 in a plurality of blocks BLK to each other. This means that NAND strings NS on the same column in the plurality of blocks BLK are connected to the same bit line BL.

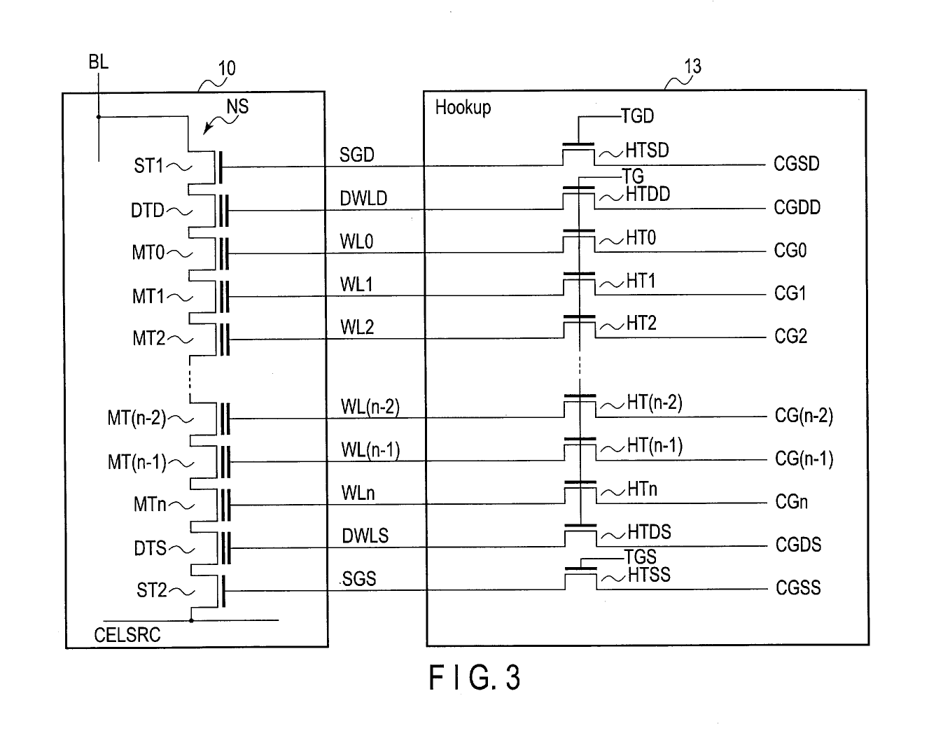

FIG. 3 is a circuit diagram of the hookup circuit 13. FIG. 3 shows only a hookup circuit connected to one block BLK.

The hookup circuit 13 includes, for each block BLK, hookup transistors in a number corresponding to the number of word lines WL0 to WLn, dummy word lines

DWLD and DWLS, and select gate lines SGD and SGS. More specifically, the current paths of hookup transistors HT0 to HTn for memory cell transistors are respectively connected in series between word lines WL0 to WLn and signal lines CG0 to CGn. The current paths of hookup transistors (dummy hookup transistors) HTDD and HTDS for dummy cell transistors are respectively connected in series between dummy word lines DWLD and DWLS and signal lines CGDD and CGDS. The current paths of hookup transistors HTSD and HTSS for select gate transistors are respectively connected in series between select gate lines SGD and SGS and signal lines CGSD and CGSS. Signal lines CG0 to CGn, CGDD, CGDS, CGSD, and CGSS are connected to a driver (not shown).

Each of hookup transistors HT0 to HTn, HTDD, HTDS, HTSD, and HTSS is formed by, for example, an N-channel MOSFET or a high-voltage transistor. A high-voltage transistor has a gate insulating film formed with a thickness larger than, for example, a select gate transistor. The gates of hookup transistors HT0 to HTn, HTDD, and HTDS are connected to a signal line TG which controls the turning on and off of these hookup transistors. Also, the gate of hookup transistor HTSD is connected to a signal line TGD which controls the turning on and off of this hookup transistor, while the gate of hookup transistor HTSS is connected to a signal line TGS which controls the turning on and off of this hookup transistor. Hookup transistors HT0 to HTn, HTDD, HTDS, HTSD, and HTSS supply predetermined voltages to word lines WL0 to WLn, dummy word lines DWLD and DWLS, and select gate lines SGD and SGS, respectively, in synchronism with reading, writing, and erasing.

### (Layout of Hookup Circuit 13)

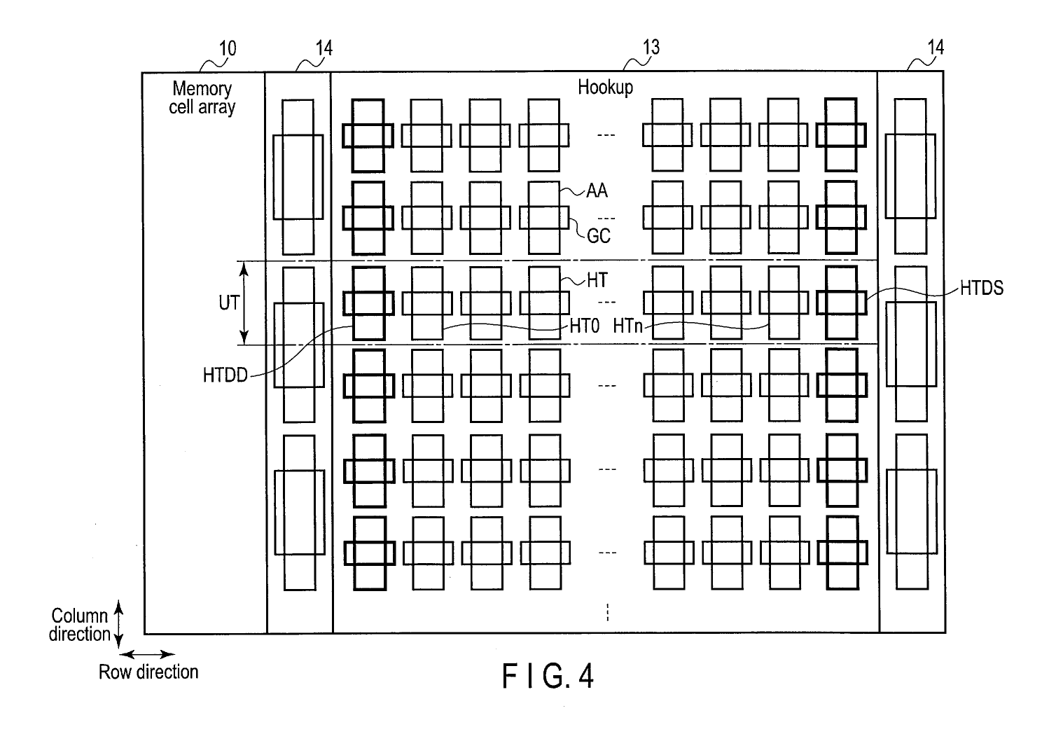

The layout of the hookup circuit 13 will be described below. FIG. 4 is a layout diagram of the hookup circuit 13. FIG. 4 corresponds to the layout of, for example, a region 15 indicated by a dotted frame in FIG. 1.

A unit UT shown in FIG. 4 is formed by hookup transistors HT0 to HTn, HTDD, HTDS, HTSD, and HTSS corresponding to one block BLK. FIG. 4 shows the layout of gate electrodes GC and active areas AA which form the hookup transistors. Layout elements indicated by thick lines in FIG. 4 show hookup transistors HTDD and HTDS, while layout elements indicated by thin lines in FIG. 4 show hookup transistors HT0 to HTn, HTSD, and HTSS.

In the first embodiment, a group of hookup transistors included in one unit UT is aligned on one row in the row direction. Hookup transistors HTDD and HTDS for dummy cell transistors are arranged at the two ends, respectively, of hookup transistors on one row. In the following description, in the unit UT, a side closer to the memory cell array 10 will be referred to as the left end, and a side farther from the memory cell array 10 will be referred to as the right end.

Dummy hookup transistors HTDD are arranged at the left end of the unit UT, while dummy hookup transistors HTDS are arranged at the right end of the unit UT. Alternatively, dummy hookup transistors HTDD may be arranged at the right end of the unit UT, while dummy hookup transistors HTDS are arranged at the left end of the unit UT. Note that the positions of hookup transistors HT0 to HTn, HTSD, and HTSS can be arbitrarily set between dummy hookup transistors HTDD and HTDS.

Peripheral circuits and guard rings 14 are arranged on the two sides of the hookup circuit 13. MOSFETs included in the peripheral circuits 14 have a layout and size different from those of the hookup transistors. Hence, the environments of the two ends of the hookup circuit 13 in the row direction are different from that of the center of the hookup circuit 13 (for example, the environment of the surrounding diffusion layer), so the characteristics of hookup transistors arranged at the two ends of the hookup circuit 13 in the row direction are different from those of hookup transistors arranged at the center of the hookup circuit 13. Also, hookup transistors arranged at the two ends of the hookup circuit 13 in the row direction are arranged in portions with a poor layout periodicity, so the shapes of the hookup transistors may deteriorate. This may degrade the characteristics of the hookup transistors.

Further, the characteristics of hookup transistors arranged near the guard rings 14 may change due to the adverse effect of an impurity in the guard rings 14. The case wherein, for example, hookup transistors are arranged on a p-type semiconductor substrate, and the guard rings 14 form n-type wells will be considered. The n-type wells of the guard rings 14 may spread to the hookup circuit 13, so it is often the case that the characteristics of hookup transistors arranged on the two sides of the hookup circuit 13 in the row direction become different from those of hookup transistors arranged at the center of the hookup circuit 13.

However, using the layout according to this embodiment, hookup transistors HT0 to HTn for memory cell transistors are arranged inside the unit UT. That is, hookup transistors HT0 to HTn are set under the same environment, and have a regularly repeated layout. This makes it possible to reduce variations and degradation in characteristics of hookup transistors HT0 to HTn.

Similarly, hookup transistors HTSD and HTSS for select gate transistors are also formed under the same conditions as hookup transistors HT0 to HTn, so it is possible to reduce variations and degradation in characteristics of hookup transistors HTSD and HTSS.

Note that even when the characteristics of hookup transistors HTDD and HTDS degrade, this poses no special problem in terms of the operation of a semiconductor memory device because dummy cell transistors DTD and DTS are not used to store data.

Also, of memory cell transistors MT0 to MTn included in the NAND string NS, memory cell transistors MT0 and MT1 arranged on the drain side, and memory cell transistors MT(n−1) and MTn arranged on the source side have a relatively high resistance against the influence of the surrounding environment (for example, voltage stress). This is because, for example, memory cell transistors MT0, MT1, MT(n−1), and MTn at the ends of the NAND string NS have write voltage levels lower than memory cell transistors MT3 to MT(n−2) at the central portion of the NAND string NS. This means that the levels of voltages applied to hookup transistors HT0, HT1, HT(n−1), and HTn connected to memory cell transistors MT0, MT1, MT(n−1), and MTn, respectively, are also lower than those of voltages applied to hookup transistors HT3 to HT(n−2).

Hence, hookup transistors HT0 and HTn connected to memory cell transistors MT0 and MTn, respectively, with a relatively high resistance against the influence of the surrounding environment (for example, voltage stress) are desirably arranged near dummy hookup transistors HTDD and HTDS, as shown in FIG. 4. With this arrangement, variations in characteristics of hookup transistors HT0 to HTn can be reduced by arranging hookup transistors HT0 and HTn at positions under environments with relatively large differences from that of the center of the hookup circuit 13.

### (Effect)

As described in detail above, according to the first embodiment, a group of hookup transistors to be connected to one block BLK is aligned on one column. The group of hookup transistors is formed by hookup transistors HT0 to HTn for memory cell transistors MT0 to MTn, hookup transistors HTSD and HTSS for select gate transistors ST1 and ST2, and dummy hookup transistors HTDD and HTDS for dummy cell transistors DTD and DTS. Dummy hookup transistors HTDD and HTDS are arranged at the two ends of the group of hookup transistors.

Hence, according to the first embodiment, hookup transistors HT0 to HTn for memory cell transistors MT0 to MTn are arranged inside a region where a group of hookup transistors is arranged. With this arrangement, hookup transistors HT0 to HTn have the same surrounding environment, so variations in their characteristics can be reduced. Variations in characteristics of hookup transistors HTSD and HTSS can similarly be reduced. This allows high-accuracy write, read, and erase operations in a semiconductor memory device.

### Second Embodiment

The second embodiment is a modification to the first embodiment, and relates to a layout in which groups of hookup transistors to be connected to one block BLK are arranged on two rows.

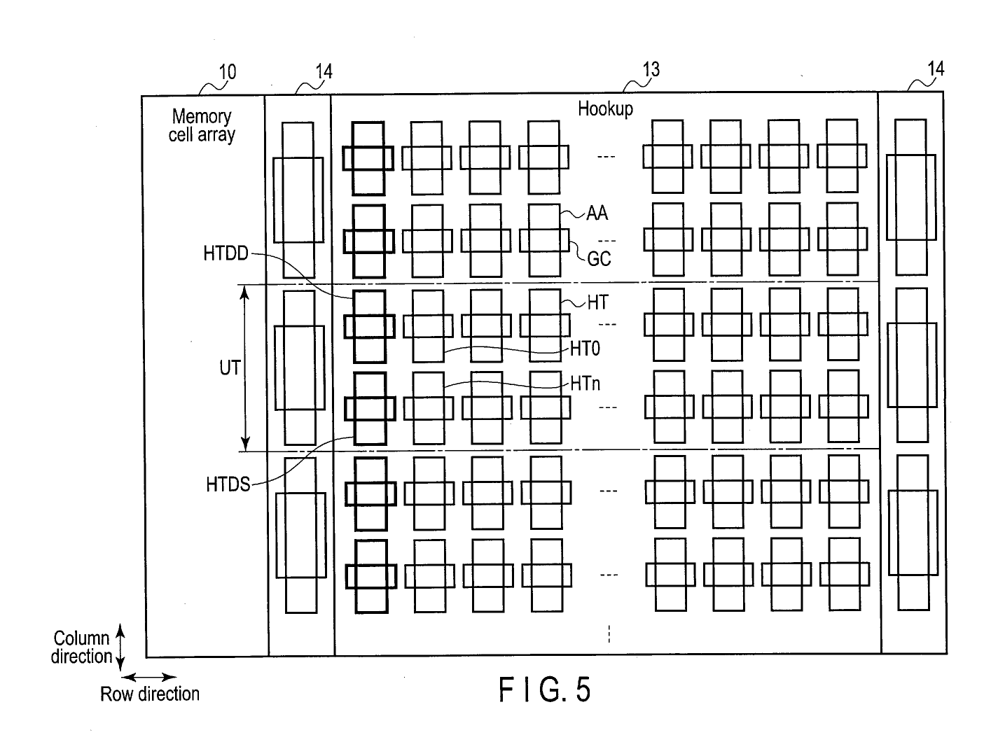

FIG. 5 is a layout diagram of a hookup circuit 13 according to the second embodiment. The circuit diagram of the hookup circuit 13 is the same as that shown in FIG. 3 described the first embodiment. A unit UT shown in FIG. 5 includes hookup transistors HT0 to HTn, HTDD, HTDS, HTSD, and HTSS corresponding to one block BLK.

In the second embodiment, groups of hookup transistors included in one unit UT are aligned on two rows in the row direction. Dummy hookup transistors HTDD and HTDS are arranged at the left end of the unit UT, that is, at the end of the unit UT on a side closer to a memory cell array 10.

In this manner, in the layout according to the second embodiment, hookup transistors HTDD and HTDS are arranged at the left end of the unit UT, so it is possible to prevent hookup transistors HT0 to HTn for memory cell transistors, and hookup transistors HTSD and HTSS for select gate transistors from being arranged in a region close to the memory cell array 10.

Because the memory cell array 10 includes very fine elements and interconnections, it has an environment considerably different from that of the hookup circuit 13. On the other hand, the peripheral circuit on the right side of the hookup circuit 13 is not as fine as the memory cell array 10, so the hookup circuit 13 and the peripheral circuit on the right side do not have too much variation in environment. Hence, dummy hookup transistors HTDD and HTDS are arranged on a side closer to the memory cell array 10, that is, the side on which the variation in environment is larger. As a result, hookup transistors HT0 to HTn, HTSD, and HTSS are set under almost the same environment, and have a regularly repeated layout. This makes it possible to reduce variations and degradation in characteristics of hookup transistors HT0 to HTn, HTSD, and HTSS.

Hookup transistors HT0 and HTn connected to memory cell transistors MT0 and MTn with a relatively high resistance against the influence of the surrounding environment (for example, voltage stress) are desirably arranged near dummy hookup transistors HTDD and HTDS. With this arrangement, variations in characteristics of hookup transistors HT0 to HTn can be reduced by arranging hookup transistors HT0 and HTn at positions under environments with relatively large differences from that of the center of the hookup circuit 13.

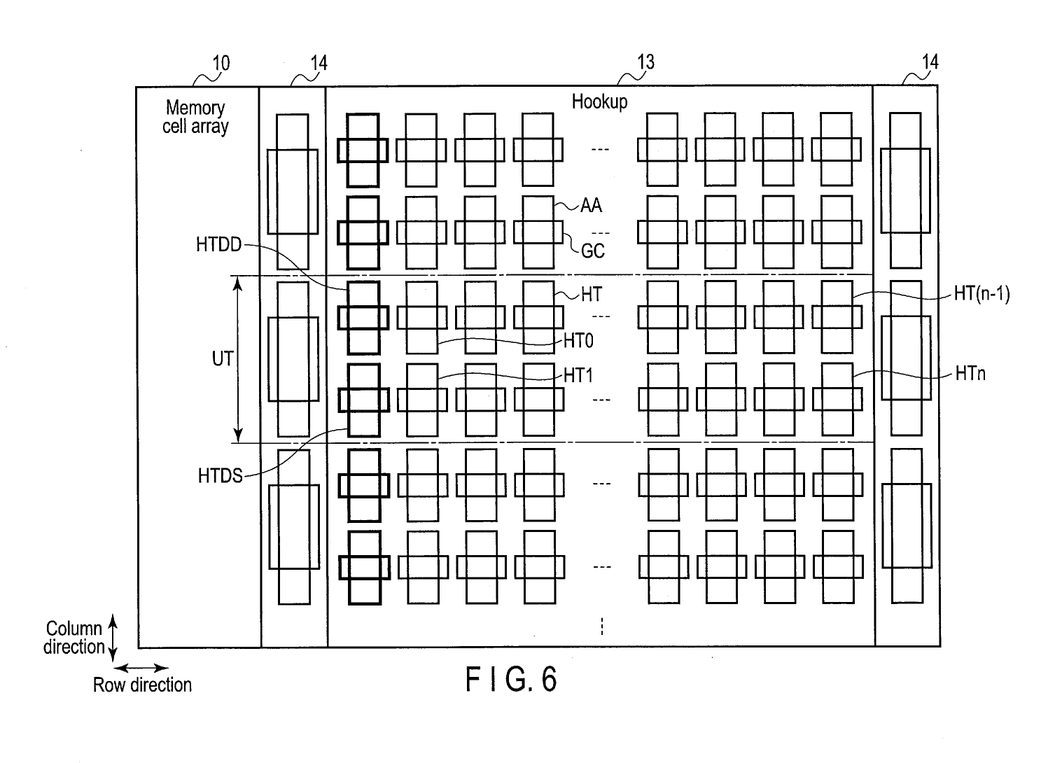

Also, the right end of the unit UT, that is, the end of the unit UT on a side farther from the memory cell array 10 is in contact with a peripheral circuit and a guard ring 14, and therefore has an environment different from that of the center of the hookup circuit 13. This may degrade the characteristics of hookup transistors arranged at the right end of the unit UT. Hence, as shown in FIG. 6, memory cell transistors MT0 and MT1 with a relatively high resistance against the influence of the surrounding environment are desirably arranged near dummy hookup transistors HTDD and HTDS, while memory cell transistors MT(n−1) and MTn with a relatively high resistance against the influence of the surrounding environment are desirably arranged at the right end of the unit UT.

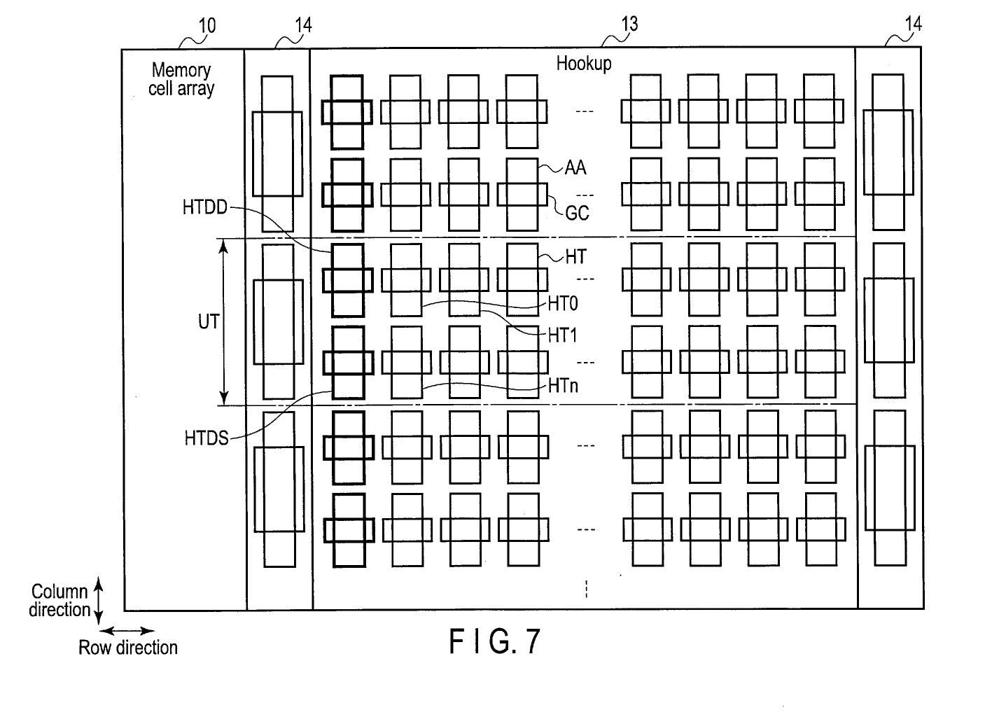

Moreover, as shown in FIG. 7, when an odd number of memory cell transistors with a relatively high resistance against the influence of the surrounding environment (for example, memory cell transistors MT0, MT, and MTn) are used, memory cell transistors MT0, MT1, and MTn are arranged near dummy hookup transistors HTDD and HTDS with small gaps between them.

### Third Embodiment

The third embodiment is a modification to the first embodiment, and relates to a layout in which groups of hookup transistors to be connected to one block BLK are arranged on two rows.

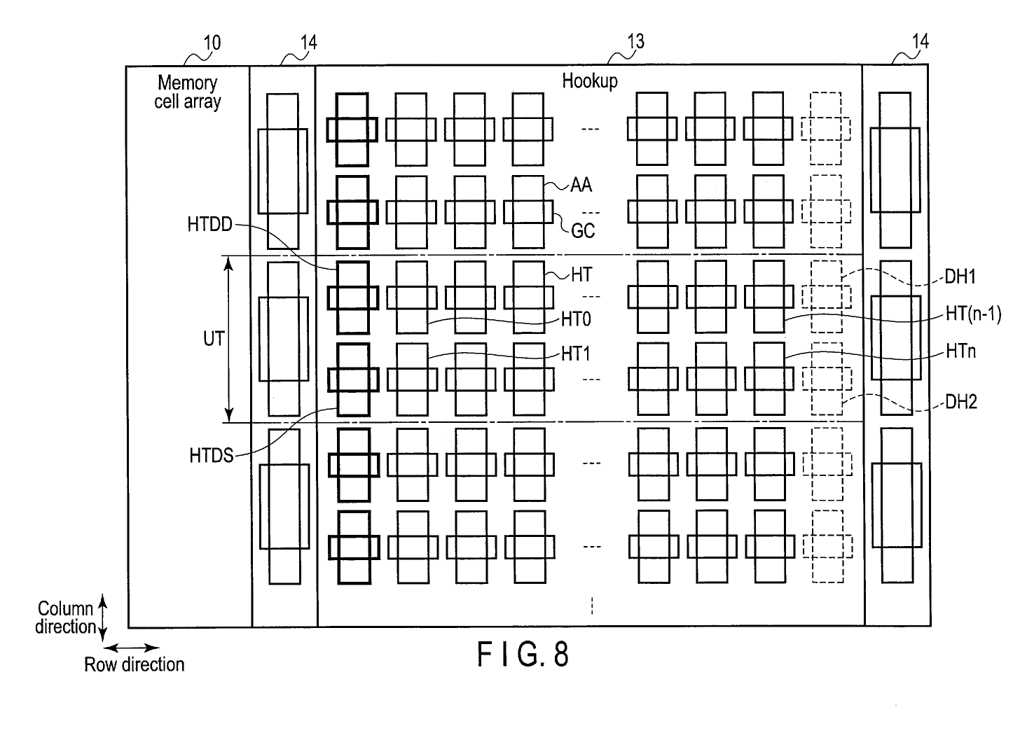

FIG. 8 is a layout diagram of a hookup circuit 13 according to the third embodiment. The circuit diagram of the hookup circuit 13 is the same as that shown in FIG. 3 described the first embodiment. A unit UT shown in FIG. 8 includes hookup transistors HT0 to HTn, HTDD, HTDS, HTSD, and HTSS corresponding to one block BLK.

In the third embodiment, groups of hookup transistors included in one unit UT are aligned on two rows in the row direction. Dummy hookup transistors HTDD and HTDS are arranged at the left end of the unit UT.

Note that dummy hookup transistors HTDD and HTDS are arranged at the left end of the unit UT, so hookup transistors for memory cell transistors or select gate transistors are arranged at the right end of the unit UT. Hence, in the third embodiment, dummy hookup transistors DH1 and DH2 are newly provided and arranged at the right end of the unit UT. That is, in the third embodiment, four dummy hookup transistors HTDD, HTDS, DH1, and DH2 are provided to one block. Referring to FIG. 8, dummy hookup transistors DH1 and DH2 have the same configuration as other hookup transistors (for example, hookup transistors for memory cell transistors), but are not connected to the memory cell array 10 and perform no operation of transferring voltages to word lines.

In this manner, in the layout according to the third embodiment, two dummy hookup transistors are arranged at each of the two ends of the unit UT. With this arrangement, hookup transistors HT0 to HTn for memory cell transistors, and hookup transistors HTSD and HTSS for select gate transistors are arranged inside the unit UT. That is, hookup transistors HT0 to HTn, HTSD, and HTSS are set under the same environment, and have a regularly repeated layout. This makes it possible to reduce variations and degradation in characteristics of hookup transistors HT0 to HTn.

Also, hookup transistors connected to memory cell transistors with a relatively high resistance against the influence of the surrounding environment (for example, voltage stress) are desirably arranged near dummy hookup transistors. For example, hookup transistors HT0 and HT1 are arranged near dummy hookup transistors HTDD and HTDS, respectively, while hookup transistors HT(n−1) and HTn are arranged near dummy hookup transistors DH1 and DH2, respectively. With this arrangement, variations in characteristics of hookup transistors HT0 to HTn can be reduced by arranging hookup transistors HT0, HT1, Ht(n−1), and HTn at positions under environments with relatively large differences from that of the center of the hookup circuit 13.

### Fourth Embodiment

The fourth embodiment is an example of the configuration of a hookup circuit when four dummy cell transistors are arranged in one NAND string NS.

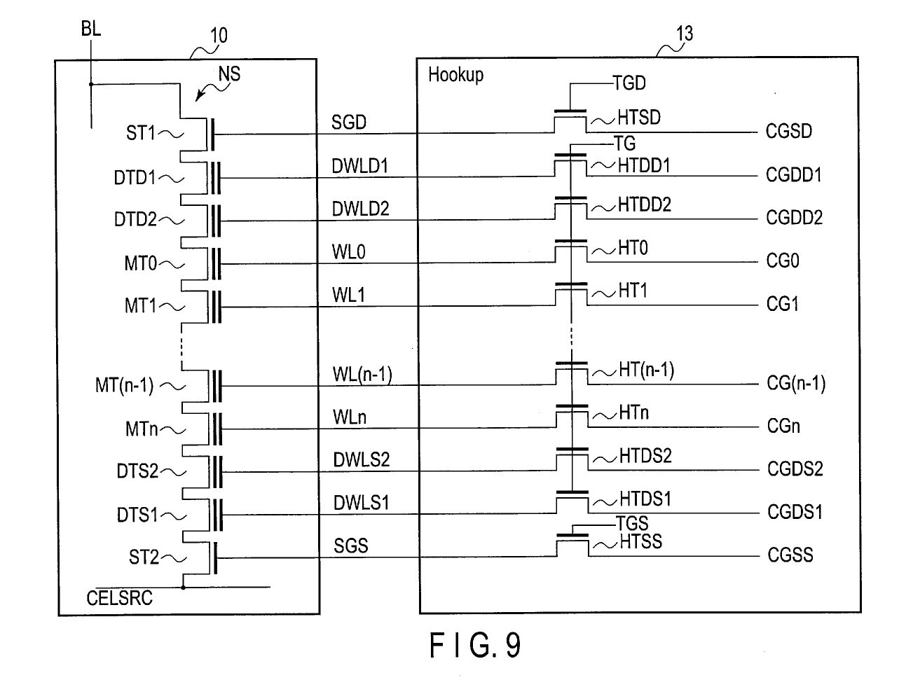

FIG. 9 is a circuit diagram of a hookup circuit 13 according to the fourth embodiment. FIG. 9 shows only a hookup circuit connected to one block BLK.

The NAND string NS included in one block BLK includes four dummy cell transistors DTD1, DTD2, DTS1, and DTS2. The current paths of the two dummy cell transistors DTD1 and DTD2 are connected in series between a memory cell transistor MT0 and select gate transistor ST1 closest to the drain in the NAND string NS. The current paths of dummy cell transistors DTS1 and DTS2 are connected in series between a memory cell transistor MTn and select gate transistor ST2 closest to the source in the NAND string NS. In this manner, the use of a larger number of dummy cell transistors than in the first embodiment makes it possible to further reduce variations in characteristics of memory cell transistors MT0 to MTn.

The control gate electrodes of dummy cell transistors DTD1 or DTD2 on the same row in the block BLK are commonly connected to a dummy word line DWLD1 or DWLD2 running in the row direction. The control gate electrodes of dummy cell transistors DTS1 or DTS2 on the same row in the block BLK are commonly connected to a dummy word line DWLS1 or DWLS2 running in the row direction.

The hookup circuit 13 includes, for each block BLK, hookup transistors in a number corresponding to the number of dummy word lines DWLD1, DWLD2, DWLS1, and DWLS2. More specifically, dummy hookup transistors HTDD1 and HTDD2 for dummy cell transistors DTD1 and DTD2 are respectively connected in series between dummy word lines DWLD1 and DWLD2 and signal lines CGDD1 and CGDD2. Dummy hookup transistors HTDS1 and HTDS2 for dummy cell transistors DTS1 and DTS2 are respectively connected in series between dummy word lines DWLS1 and DWLS2 and signal lines CGDS1 and CGDS2.

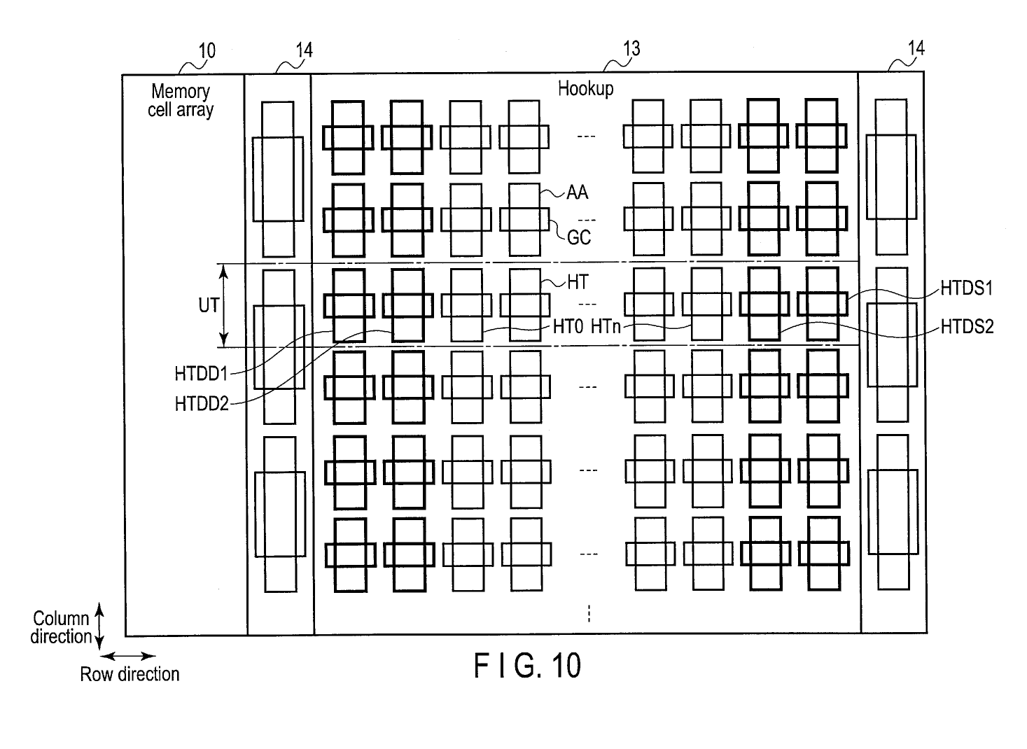

The layout of the hookup circuit 13 will be described below. FIG. 10 is a layout diagram of the hookup circuit 13. A unit UT shown in FIG. 10 is formed by hookup transistors HT0 to HTn, HTDD1, HTDD2, HTDS1, HTDS2, HTSD, and HTSS corresponding to one block BLK.

In the fourth embodiment, a group of hookup transistors included in one unit UT is aligned on one row in the row direction. Two hookup transistors for dummy cell transistors are arranged at each of the two ends of the unit UT. That is, dummy hookup transistors HTDD1 and HTDD2 for dummy cell transistors DTD1 and DTD2 are arranged at the left end of the unit UT, while dummy hookup transistors HTDS1 and HTDS2 for dummy cell transistors DTS1 and DTS2 are arranged at the right end of the unit UT. Alternatively, dummy hookup transistors HTDD1 and HTDD2 may be arranged at the right end of the unit UT, while dummy hookup transistors HTDS1 and HTDS2 are arranged at the left end of the unit UT. Again, one of dummy hookup transistors HTDD1 and HTDD2, and one of dummy hookup transistors HTDS1 and HTDS2 may be arranged at the left end of the unit UT, while the other of dummy hookup transistors HTDD1 and HTDD2, and the other of dummy hookup transistors HTDS1 and HTDS2 are arranged at the right end of the unit UT.

In this manner, in the layout according to the fourth embodiment, two dummy hookup transistors are arranged at each of the two ends of the unit UT. With this arrangement, hookup transistors HT0 to HTn for memory cell transistors, and hookup transistors HTSD and HTSS for select gate transistors are arranged inside the unit UT. That is, hookup transistors HT0 to HTn, HTSD, and HTSS are set under the same environment, and have a regularly repeated layout. This makes it possible to reduce variations and degradation in characteristics of hookup transistors HT0 to HTn, HTSD, and HTSS.

Also, hookup transistors HT0 and HTn connected to memory cell transistors MT0 and MTn, respectively, with a relatively high resistance against the influence of the surrounding environment (for example, voltage stress) are desirably arranged near dummy hookup transistors HTDD2 and HTDS2. With this arrangement, variations in characteristics of hookup transistors HT0 to HTn can be reduced by arranging hookup transistors HT0 and HTn at positions under environments with relatively large differences from that of the center of the hookup circuit 13.

### Fifth Embodiment

The fifth embodiment is a modification to the fourth embodiment, and relates to a layout in which dummy hookup transistors are unevenly arranged at the two ends of a unit UT.

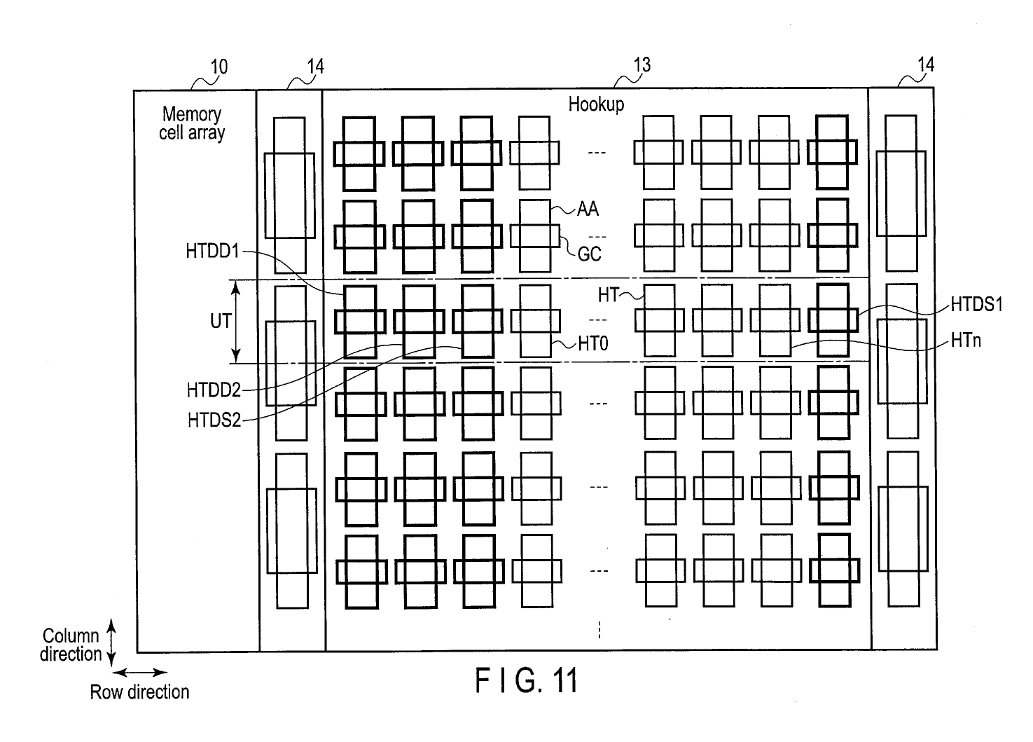

FIG. 11 is a layout diagram of a hookup circuit 13 according to the fifth embodiment. The hookup circuit 13 includes four dummy hookup transistors HTDD1, HTDD2, HTDS1, and HTDS2 for each block BLK, as in the fourth embodiment.

A group of hookup transistors included in one unit UT is aligned on one row in the row direction. Three of the four dummy hookup transistors are arranged at the left end of the unit UT, while the remaining one is arranged at the right end of the unit UT. Referring to FIG. 11, for example, dummy hookup transistors HTDD1, HTDD2, and HTDS2 are arranged at the left end of the unit UT, while dummy hookup transistor HTDS1 is arranged at the right end of the unit UT. Alternatively, three of the four dummy hookup transistors may be arranged at the right end of the unit UT, while the remaining one is arranged at the left end of the unit UT.

Because a memory cell array 10 includes very fine elements and interconnections, it has an environment considerably different from that of the hookup circuit 13. On the other hand, the peripheral circuit on the right side of the hookup circuit 13 is not as fine as the memory cell array 10, so the hookup circuit 13 and the peripheral circuit on the right side do not have too much variation in environment. Hence, dummy hookup transistors HTDD1, HTDD2, and HTDS2 are arranged on a side closer to the memory cell array 10, that is, the side on which the variation in environment is larger. That is, the number of hookup transistors arranged on a side closer to the memory cell array 10 is larger than the number of hookup transistors arranged on a side closer to the memory cell array 10. This makes it possible to reduce variations and degradation in characteristics of hookup transistors HT0 to HTn, HTSD, and HTSS.

When the layout according to the fifth embodiment is adopted, it is also possible to reduce variations and degradation in characteristics of hookup transistors HT0 to HTn, HTSD, and HTSS.

Also, hookup transistors HT0 and HTn connected to memory cell transistors MT0 and MTn, respectively, with a relatively high resistance against the influence of the surrounding environment (for example, voltage stress) are desirably arranged near dummy hookup transistors HTDS2 and HTDS1, respectively.

### Sixth Embodiment

The sixth embodiment is a modification to the fourth embodiment, and relates to a layout in which groups of hookup transistors to be connected to one block BLK are arranged on two rows.

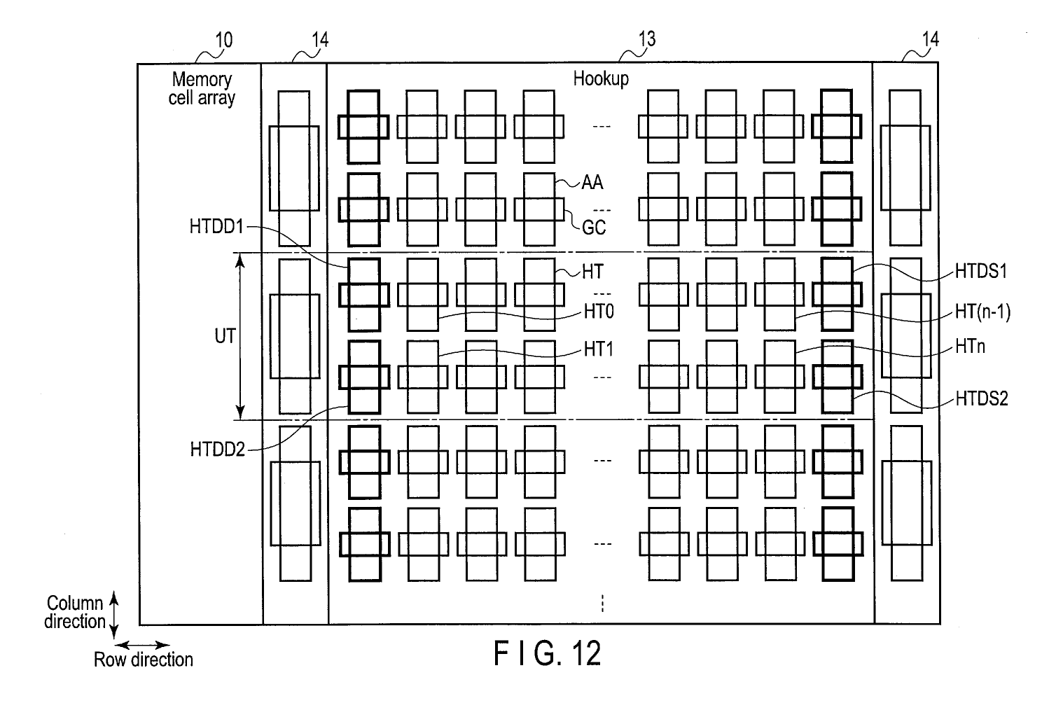

FIG. 12 is a layout diagram of a hookup circuit 13 according to the sixth embodiment. The hookup circuit 13 includes four dummy hookup transistors HTDD1, HTDD2, HTDS1, and HTDS2 for each block BLK, as in the fourth embodiment.

Groups of hookup transistors included in one unit UT are aligned on two rows in the row direction. Two of the four dummy hookup transistors are arranged at each of the two ends of the unit UT. Referring to FIG. 12, for example, dummy hookup transistors HTDD1 and HTDD2 are arranged at the left end of the unit UT, while dummy hookup transistors HTDS1 and HTDS2 are arranged at the right end of the unit UT. Alternatively, dummy hookup transistors HTDD1 and HTDD2 may be arranged at the right end of the unit UT, while dummy hookup transistors HTDS1 and HTDS2 are arranged at the left end of the unit UT.

When the layout according to the sixth embodiment is adopted, it is also possible to reduce variations and degradation in characteristics of hookup transistors HT0 to HTn, HTSD, and HTSS.

Also, hookup transistors HT0, HT1, HT(n−1), and HTn connected to memory cell transistors MT0, MT1, MT(n−1), and MTn, respectively, with a relatively high resistance against the influence of the surrounding environment (for example, voltage stress) are desirably arranged near dummy hookup transistors HTDD1, HTDD2, HTDS1, and HTDS2, respectively.

### Seventh Embodiment

The seventh embodiment is a modification to the fourth embodiment, and relates to a layout in which dummy hookup transistors are collectively arranged at one end of a unit UT.

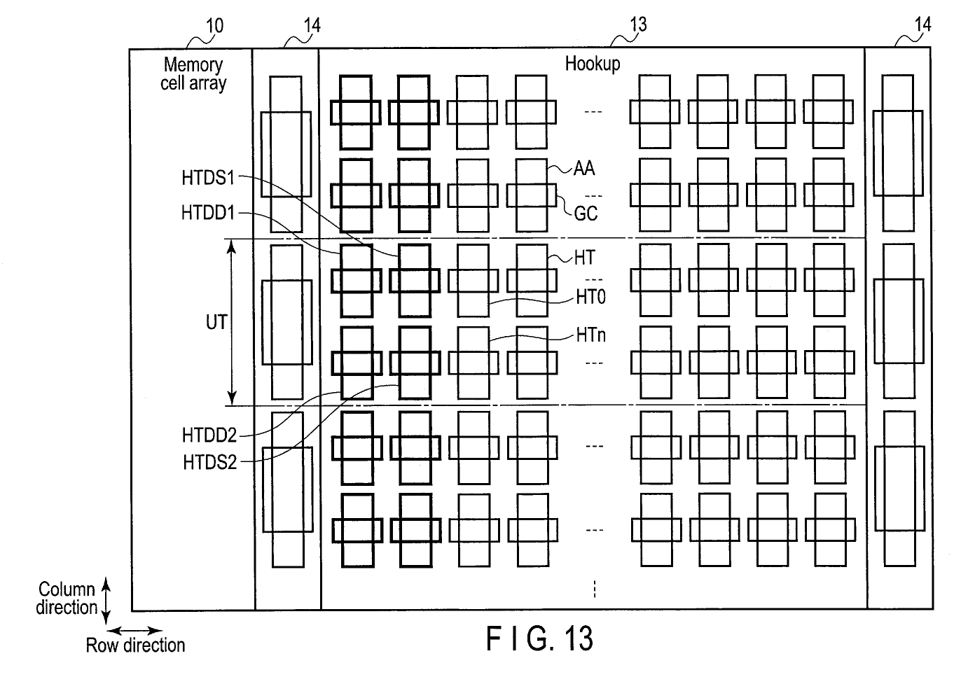

FIG. 13 is a layout diagram of a hookup circuit 13 according to the seventh embodiment. The hookup circuit 13 includes four dummy hookup transistors HTDD1, HTDD2, HTDS1, and HTDS2 for each block BLK, as in the fourth embodiment.

Groups of hookup transistors included in one unit UT are aligned on two rows in the row direction. The four dummy hookup transistors HTDD1, HTDD2, HTDS1, and HTDS2 are collectively arranged at the left end of the unit UT.

When the layout according to the seventh embodiment is adopted, it is also possible to reduce variations and degradation in characteristics of hookup transistors HT0 to HTn, HTSD, and HTSS.

Also, dummy hookup transistors DH1 and DH2 which are not to be connected to a memory cell array 10 may be arranged at the right end of the unit UT, as in the third embodiment.

Moreover, hookup transistors HT0 and HTn connected to memory cell transistors MT0 and MTn, respectively, with a relatively high resistance against the influence of the surrounding environment are desirably arranged near dummy hookup transistors HTDS2 and HTDS1, respectively.

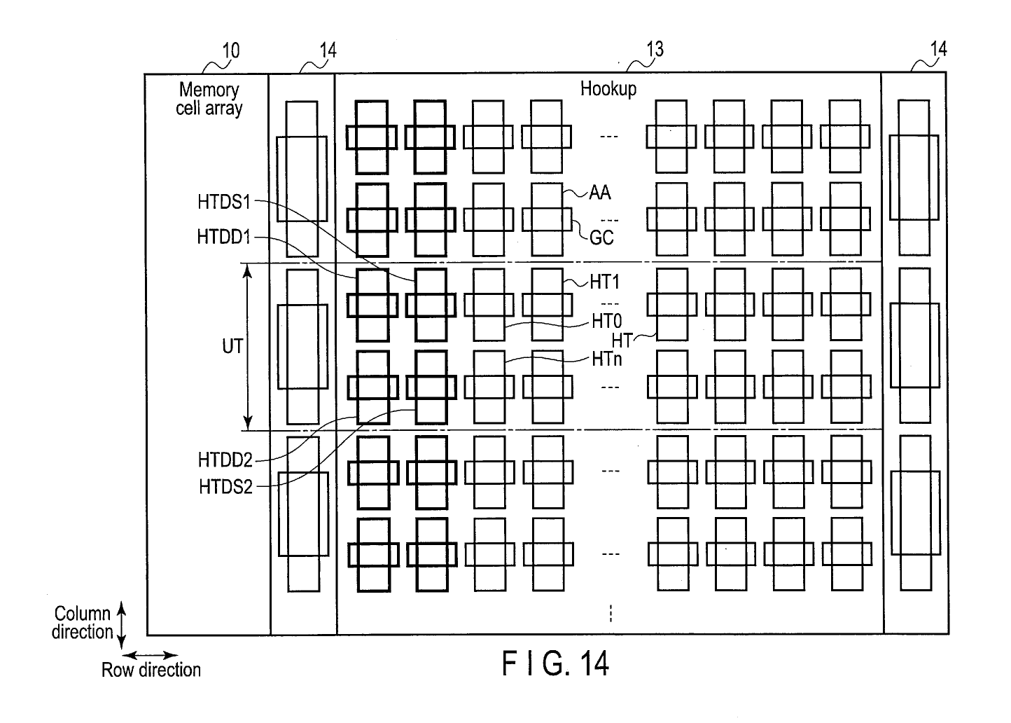

Again, as shown in FIG. 14, when an odd number of memory cell transistors with a relatively high resistance against the influence of the surrounding environment (for example, memory cell transistors MT0, MT, and MTn) are used, memory cell transistors MT0, MT1, and MTn are arranged near dummy hookup transistors HTDD and HTDS with small gaps between them.

### Eighth Embodiment

The eighth embodiment is an example of the configuration of a hookup circuit when six dummy cell transistors are arranged in one NAND string NS.

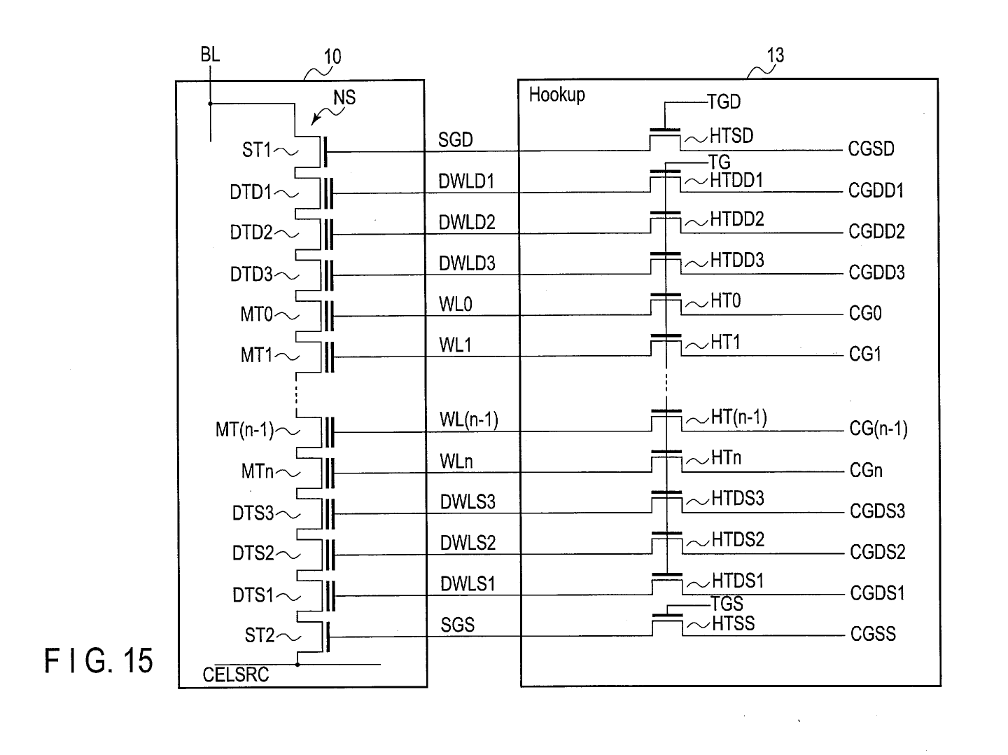

FIG. 15 is a circuit diagram of a hookup circuit 13 according to the eighth embodiment. FIG. 15 shows only a hookup circuit connected to one block BLK.

The NAND string NS included in one block BLK includes six dummy cell transistors DTD1 to DTD3 and DTS1 to DTS3. The current paths of the three dummy cell transistors DTD1 to DTD3 are connected in series between a memory cell transistor MT0 and select gate transistor ST1 closest to the drain in the NAND string NS. The current paths of dummy cell transistors DTS1 to DTS3 are connected in series between a memory cell transistor MTn and select gate transistor ST2 closest to the source in the NAND string NS. With this arrangement, the use of a larger number of dummy cell transistors than in the fourth embodiment makes it possible to further reduce variations in characteristics of memory cell transistors MT0 to MTn.

The control gate electrodes of dummy cell transistors DTD1 to DTD3 on the same row in the block BLK are commonly connected to dummy word lines DWLD1 to DWLD3, respectively, running in the row direction. The control gate electrodes of dummy cell transistors DTS1 to DTS3 on the same row in the block BLK are commonly connected to dummy word lines DWLS1 to DWLS3, respectively, running in the row direction.

The hookup circuit 13 includes, for each block BLK, hookup transistors in a number corresponding to the number of dummy word lines DWLD1 to DWLD3 and DWLS1 to DWLS3. More specifically, the current paths of dummy hookup transistors HTDD1 to HTDD3 for dummy cell transistors DTD1 to DTD3 are respectively connected in series between dummy word lines DWLD1 to DWLD3 and signal lines CGDD1 to CGDD3. The current paths of dummy hookup transistors HTDS1 to HTDS3 for dummy cell transistors DTS1 to DTS3 are respectively connected in series between dummy word lines DWLS1 to DWLS3 and signal lines CGDS1 to CGDS3.

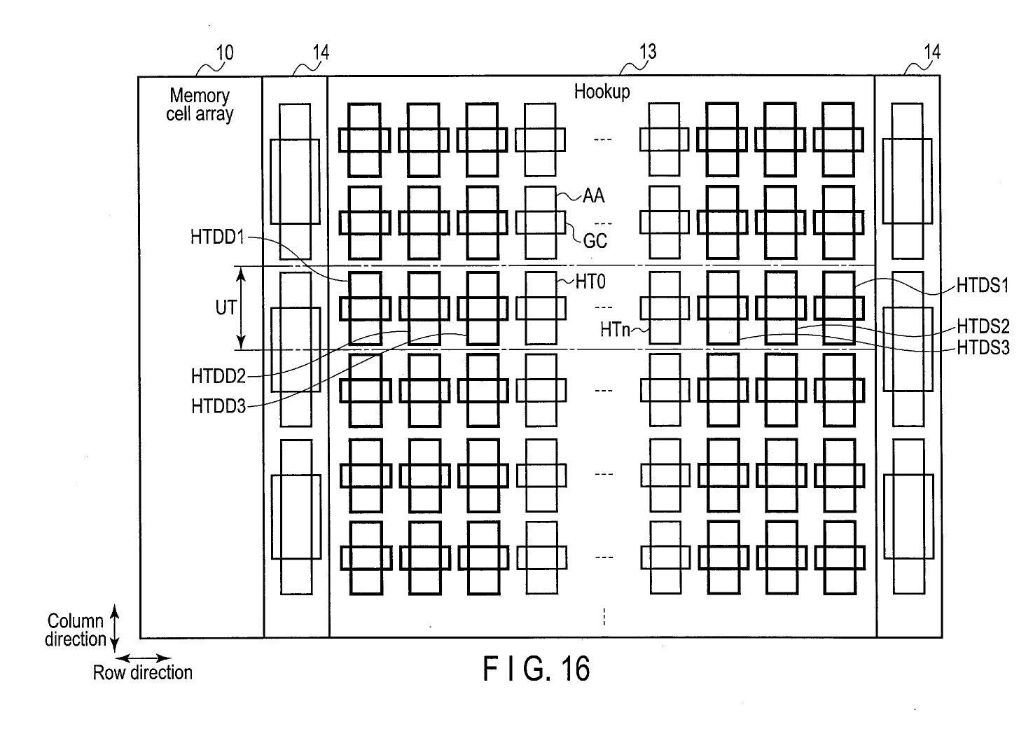

The layout of the hookup circuit 13 will be described below. FIG. 16 is a layout diagram of the hookup circuit 13. A unit UT shown in FIG. 16 is formed by hookup transistors HT0 to HTn, HTDD1 to HTDD3, HTDS1 to HTDS3, HTSD, and HTSS corresponding to one block BLK.

In the eighth embodiment, a group of hookup transistors included in one unit UT is aligned on one row in the row direction. Three hookup transistors for dummy cell transistors are arranged at each of the two ends of the unit UT. That is, dummy hookup transistors HTDD1 to HTDD3 for dummy cell transistors DTD1 to DTD3 are arranged at the left end of the unit UT, while dummy hookup transistors HTDS1 to HTDS3 for dummy cell transistors DTS1 to DTS3 are arranged at the right end of the unit UT. Alternatively, dummy hookup transistors HTDD1 to HTDD3 may be arranged at the right end of the unit UT, while dummy hookup transistors HTDS1 to HTDS3 are arranged at the left end of the unit UT. Again, an arbitrary three of dummy hookup transistors HTDD1 to HTDD3 and HTDS1 to HTDS3 may be arranged at the left end of the unit UT, while the remaining three are arranged at the right end of the unit UT.

In this manner, in the layout according to the eighth embodiment, three dummy hookup transistors are arranged at each of the two ends of the unit UT. With this arrangement, hookup transistors HT0 to HTn for memory cell transistors, and hookup transistors HTSD and HTSS for select gate transistors are arranged inside the unit UT. That is, hookup transistors HT0 to HTn, HTSD, and HTSS are set under the same environment, and have a regularly repeated layout. This makes it possible to reduce variations and degradation in characteristics of hookup transistors HT0 to HTn, HTSD, and HTSS.

Note that four of the six dummy hookup transistors may be arranged at the left end of the unit UT, while the remaining two are arranged at the right end of the unit UT. Alternatively, two of the six dummy hookup transistors may be arranged at the left end of the unit UT, while the remaining four are arranged at the right end of the unit UT.

Also, hookup transistors HT0 and HTn connected to memory cell transistors MT0 and MTn, respectively, with a relatively high resistance against the influence of the surrounding environment are desirably arranged near dummy hookup transistors HTDD3 and HTDS3, respectively.

### Ninth Embodiment

The ninth embodiment is a modification to the eighth embodiment, and relates to a layout in which groups of hookup transistors to be connected to one block BLK are arranged on two rows.

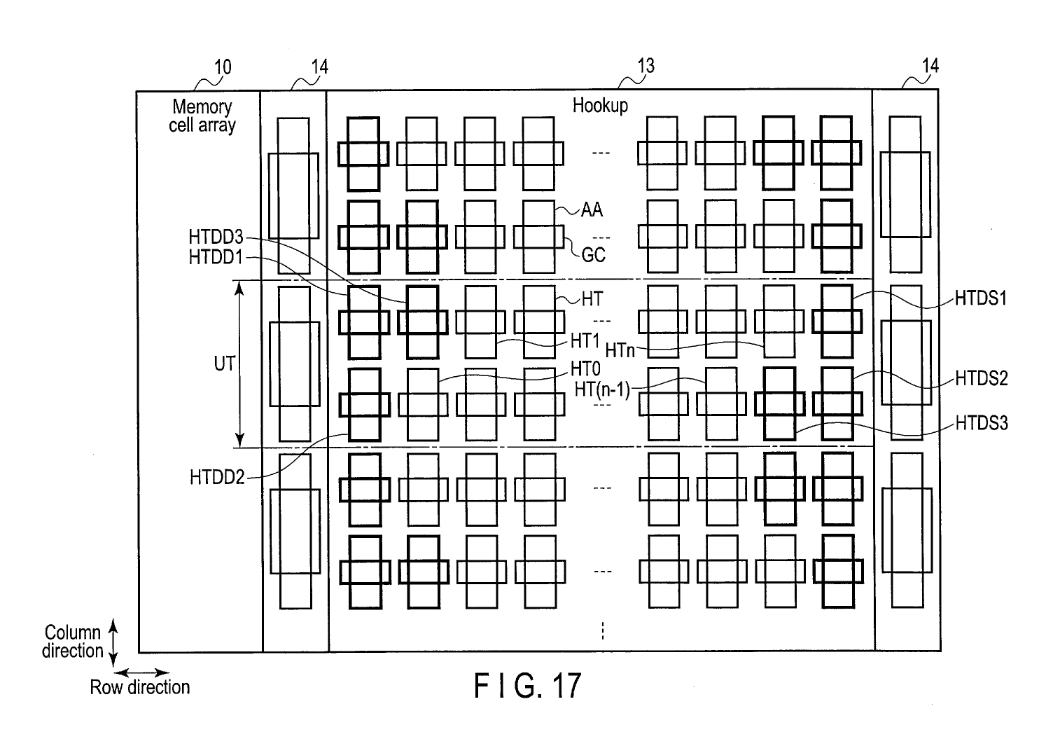

FIG. 17 is a layout diagram of a hookup circuit 13 according to the ninth embodiment. The hookup circuit 13 includes six dummy hookup transistors HTDD1 to HTDD3 and HTDS1 to HTDS3 for each block BLK, as in the eighth embodiment.

Groups of hookup transistors included in one unit UT are aligned on two rows in the row direction. Three of the six dummy hookup transistors are arranged at each of the two ends of the unit UT. Referring to FIG. 17, for example, dummy hookup transistors HTDD1 to HTDD3 are arranged at the left end of the unit UT, while dummy hookup transistors HTDS1 to HTDS3 are arranged at the right end of the unit UT. Alternatively, dummy hookup transistors HTDD1 to HTDD3 may be arranged at the right end of the unit UT, while dummy hookup transistors HTDS1 to HTDS3 are arranged at the left end of the unit UT.

Note that dummy hookup transistors are arranged in an L or inverted L shape. Two groups of dummy hookup transistors on the two sides, respectively, of the hookup circuit 13 have point symmetry, as shown in FIG. 17. When the layout of word lines WL in each block of a memory cell array 10 has symmetry in the column direction, that of dummy hookup transistors preferably has symmetry in the column direction. This makes it easy to lay out upper layer interconnections which connect the word lines and the hookup transistors to each other.

Note that dummy hookup transistors may be arranged in an L or inverted L shape in all blocks. Alternatively, dummy hookup transistors may be arranged in an L or inverted L shape both at the right and left ends. Again, dummy hookup transistors may be randomly arranged in an L or inverted L shape in respective blocks.

When the layout according to the ninth embodiment is adopted, it is also possible to reduce variations and degradation in characteristics of hookup transistors HT0 to HTn, HTSD, and HTSS.

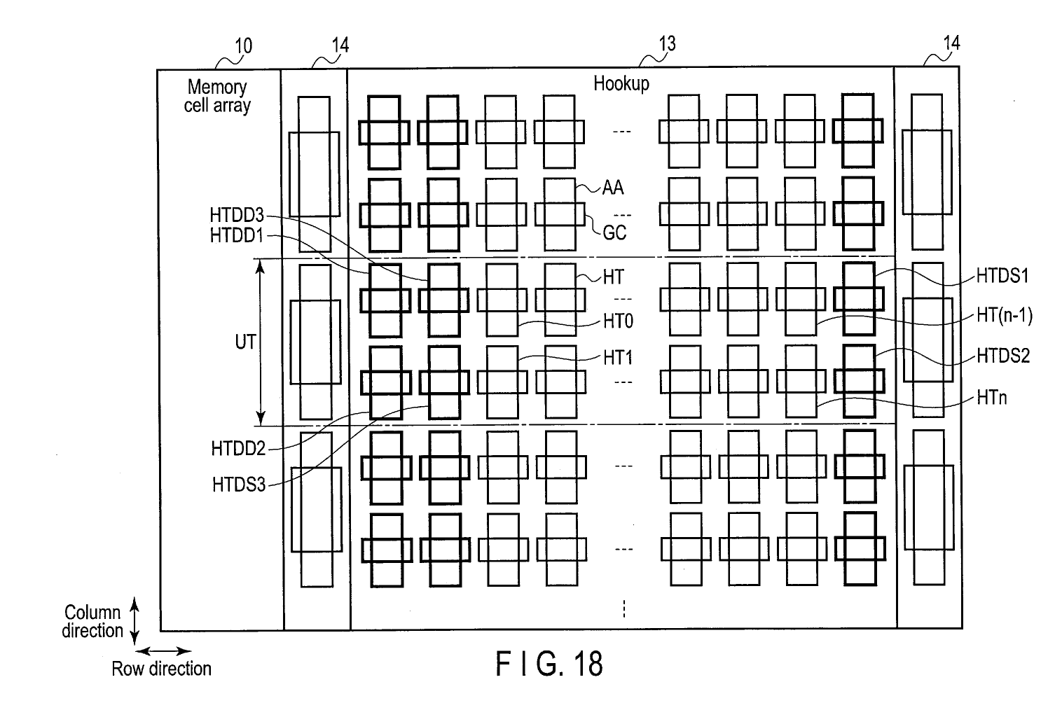

Note that four of the six dummy hookup transistors may be arranged at the left end of the unit UT, while the remaining two are arranged at the right end of the unit UT, as shown in FIG. 18. In an example shown in FIG. 18, dummy hookup transistors HTDD1 to HTDD3 and HTDS3 are arranged at the left end of the unit UT, while dummy hookup transistors HTDS1 and HTDS2 are arranged at the right end of the unit UT. Alternatively, two of the six dummy hookup transistors may be arranged at the left end of the unit UT, while the remaining four are arranged at the right end of the unit UT.

Also, hookup transistors HT0, HT1, HT(n−1), and HTn connected to memory cell transistors MT0, MT1, MT(n−1), and MTn, respectively, with a relatively high resistance against the influence of the surrounding environment are desirably arranged near the dummy hookup transistors.

### Tenth Embodiment

The tenth embodiment is a modification to the eighth embodiment, and relates to a layout in which groups of hookup transistors to be connected to one block BLK are arranged on three rows.

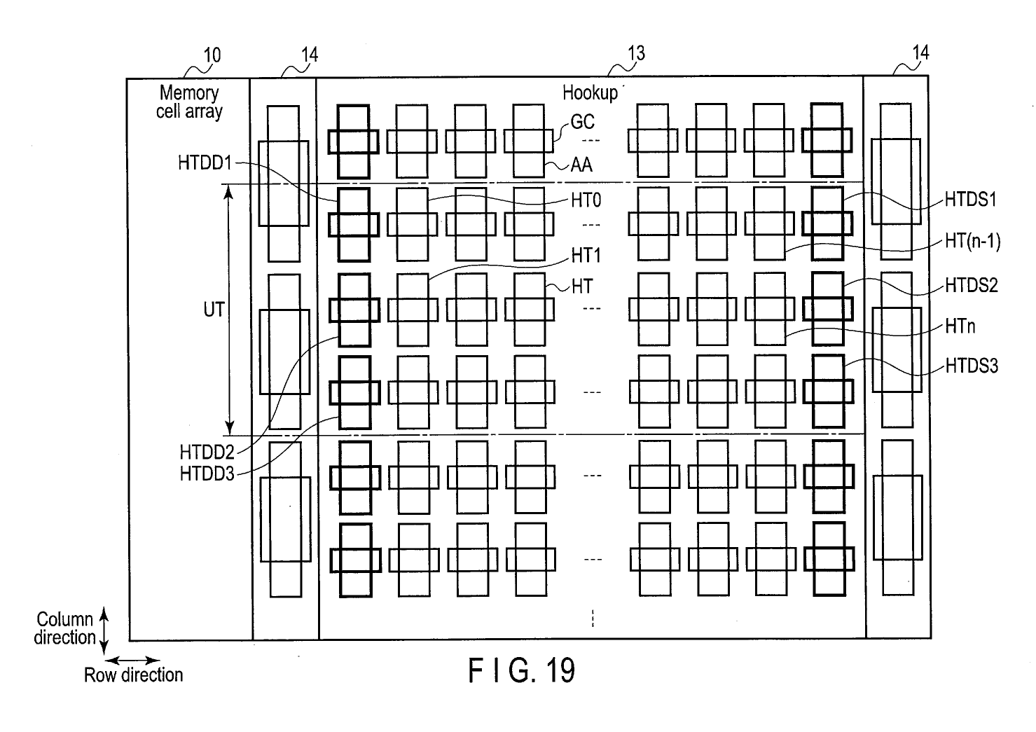

FIG. 19 is a layout diagram of a hookup circuit 13 according to the tenth embodiment. The hookup circuit 13 includes six dummy hookup transistors HTDD1 to HTDD3 and HTDS1 to HTDS3 for each block BLK, as in the eighth embodiment.

Groups of hookup transistors included in one unit UT are aligned on three rows in the row direction. Three of the six dummy hookup transistors are arranged at each of the two ends of the unit UT. Referring to FIG. 15, for example, dummy hookup transistors HTDD1 to HTDD3 are aligned on one column at the left end of the unit UT, while dummy hookup transistors HTDS1 to HTDS3 are aligned on one column at the right end of the unit UT. Alternatively, dummy hookup transistors HTDD1 to HTDD3 may be arranged on one column at the right end of the unit UT, while dummy hookup transistors HTDS1 to HTDS3 are arranged on one column at the left end of the unit UT.

When the layout according to the tenth embodiment is adopted, it is also possible to reduce variations and degradation in characteristics of hookup transistors HT0 to HTn, HTSD, and HTSS.

Also, hookup transistors HT0, HT1, HT(n−1), and HTn connected to memory cell transistors MT0, MT1, MT(n−1), and MTn, respectively, with a relatively high resistance against the influence of the surrounding environment are desirably arranged near the dummy hookup transistors.

### Eleventh Embodiment

It is often the case that eight or more dummy cell transistors are necessary for a NAND string NS, that is, four or more dummy transistors are necessary for each of the drain and source sides of the NAND string NS, in accordance with the characteristics of a memory cell transistor MT. The number of dummy cell transistors included in the NAND string NS is defined as N (N is an integer of 8 or more), and hookup transistors included in one unit UT are aligned on M rows (M is an integer of 2 or more) in the row direction.

The layout of a hookup circuit 13 under such conditions will be described below.

If N≧2×M, N dummy hookup transistors corresponding to N dummy cell transistors are provided in the hookup circuit 13. One or a plurality of dummy hookup transistors of the N dummy hookup transistors are arranged at the left end of the unit UT, while the remaining dummy hookup transistors are arranged at the right end of the unit UT.

If N<2×M, N dummy hookup transistors corresponding to N dummy cell transistors are insufficient to fill all cells at the two ends of a unit formed by hookup transistors on M rows. In this case, (2×M−N) or more dummy hookup transistors are newly provided in addition to the N dummy hookup transistors, as in the third embodiment. One or a plurality of dummy hookup transistors of all the dummy hookup transistors are arranged at the left end of the unit UT, while the remaining dummy hookup transistors are arranged at the right end of the unit UT.

Dummy hookup transistors can fill all cells at the two ends of a unit by laying them out in accordance with the conditions as mentioned above. This makes it possible to reduce variations and degradation in characteristics of hookup transistors HT0 to HTn, HTSD, and HTSS.

Although an example in which equal numbers of dummy cell transistors are arranged on the drain and source sides of the NAND string NS has been given in the above-mentioned embodiment, different numbers of dummy cell transistors may be arranged on the drain and source sides of the NAND string NS. That is, the number of dummy cell transistors DTD on the drain side of the NAND string NS may be different from the number of dummy cell transistors DTS on the source side of the NAND string NS. In this case, the number of dummy hookup transistors is also different between the drain and source sides.

### Twelfth Embodiment

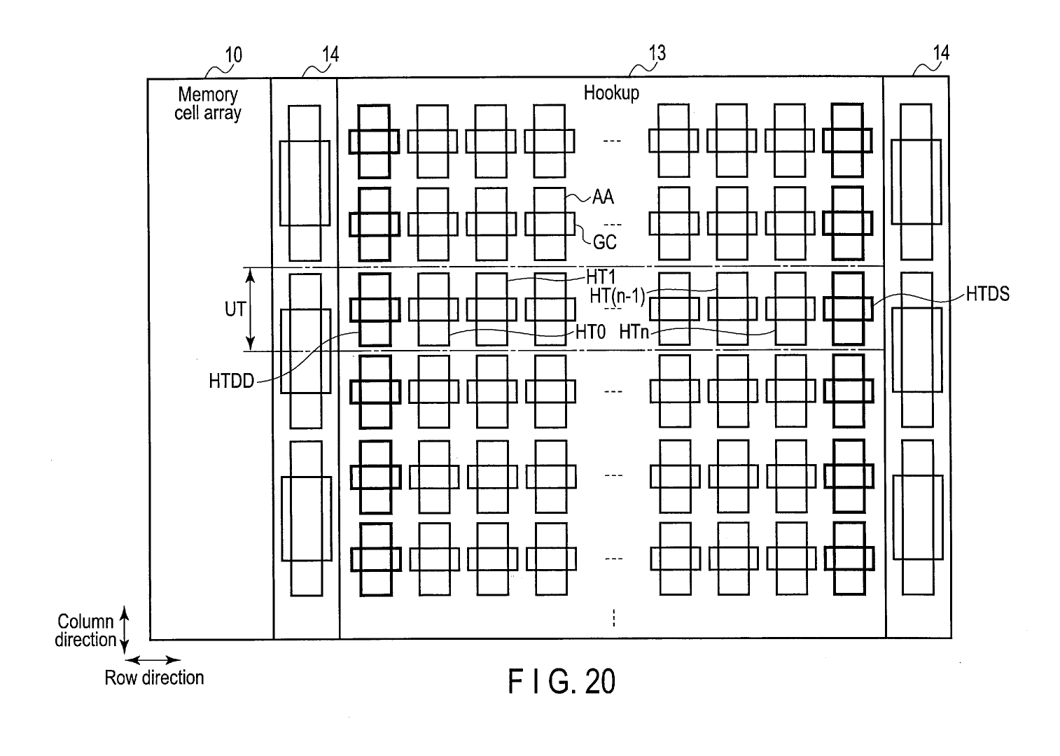

The twelfth embodiment is an example of the configuration of a hookup circuit when two dummy cell transistors are arranged in one NAND string NS. FIG. 20 is a circuit diagram of a hookup circuit 13 according to the twelfth embodiment.

A group of hookup transistors included in one unit UT is aligned on one row in the row direction. Hookup transistors HTDD and HTDS for dummy cell transistors are arranged at the two ends, respectively, of hookup transistors on one row.

Hookup transistors connected to memory cell transistors with a relatively high resistance against the influence of the surrounding environment (for example, voltage stress) are desirably arranged near dummy hookup transistors. For example, hookup transistors HT0 and HT1 are arranged near the dummy hookup transistor HTDD, while hookup transistors HT(n−1) and HTn are arranged near dummy hookup transistor HTDS. With this arrangement, variations in characteristics of hookup transistors HT0 to HTn can be reduced by arranging hookup transistors HT0, HT1, Ht(n−1), and HTn at positions under environments with relatively large differences from that of the center of the hookup circuit 13.

### Thirteenth Embodiment

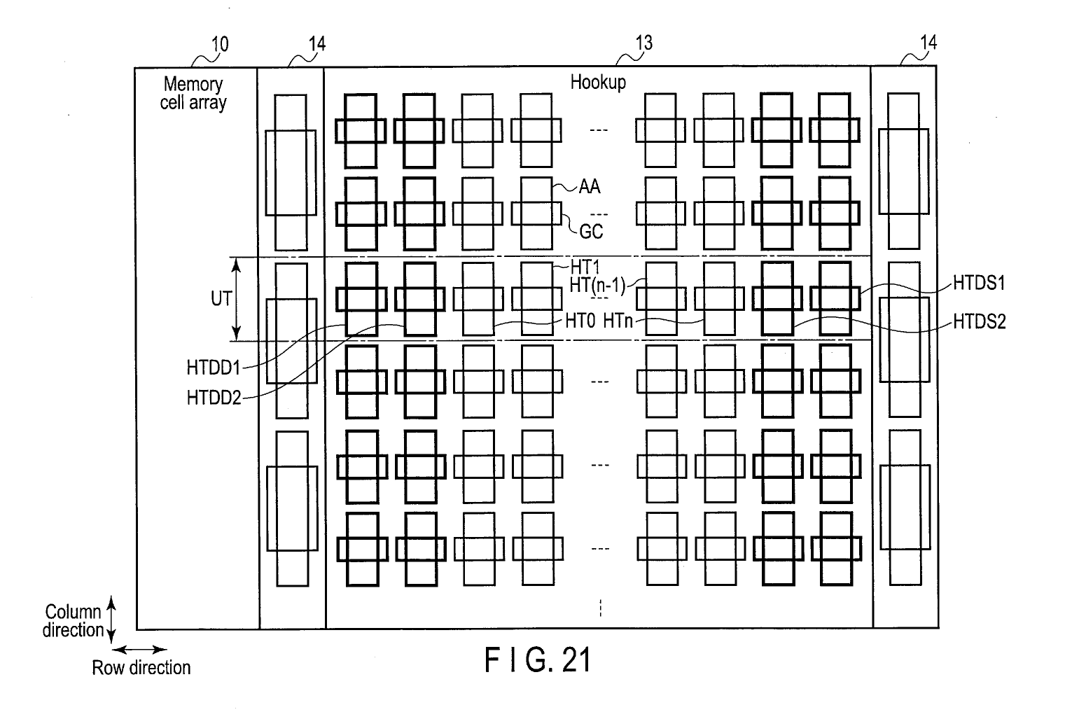

The thirteenth embodiment is an example of the configuration of a hookup circuit when four dummy cell transistors are arranged in one NAND string NS. FIG. 21 is a circuit diagram of a hookup circuit 13 according to the thirteenth embodiment.

A group of hookup transistors included in one unit UT is aligned on one row in the row direction. Two hookup transistors for dummy cell transistors are arranged at each of the two ends of the unit UT. For example, dummy hookup transistors HTDD1 and HTDD2 for dummy cell transistors DTD1 and DTD2 are arranged at the left end of the unit UT, while dummy hookup transistors HTDS1 and HTDS2 for dummy cell transistors DTS1 and DTS2 are arranged at the right end of the unit UT.

Hookup transistors HT0 and HT1 are arranged near the dummy hookup transistors HTDD1 and HTDD2, while hookup transistors HT(n−1) and HTn are arranged near dummy hookup transistors HTDS1 and HTDS2. With this arrangement, variations in characteristics of hookup transistors HT0 to HTn can be reduced by arranging hookup transistors HT0, HT1, Ht(n−1), and HTn at positions under environments with relatively large differences from that of the center of the hookup circuit 13.

### Fourteenth Embodiment

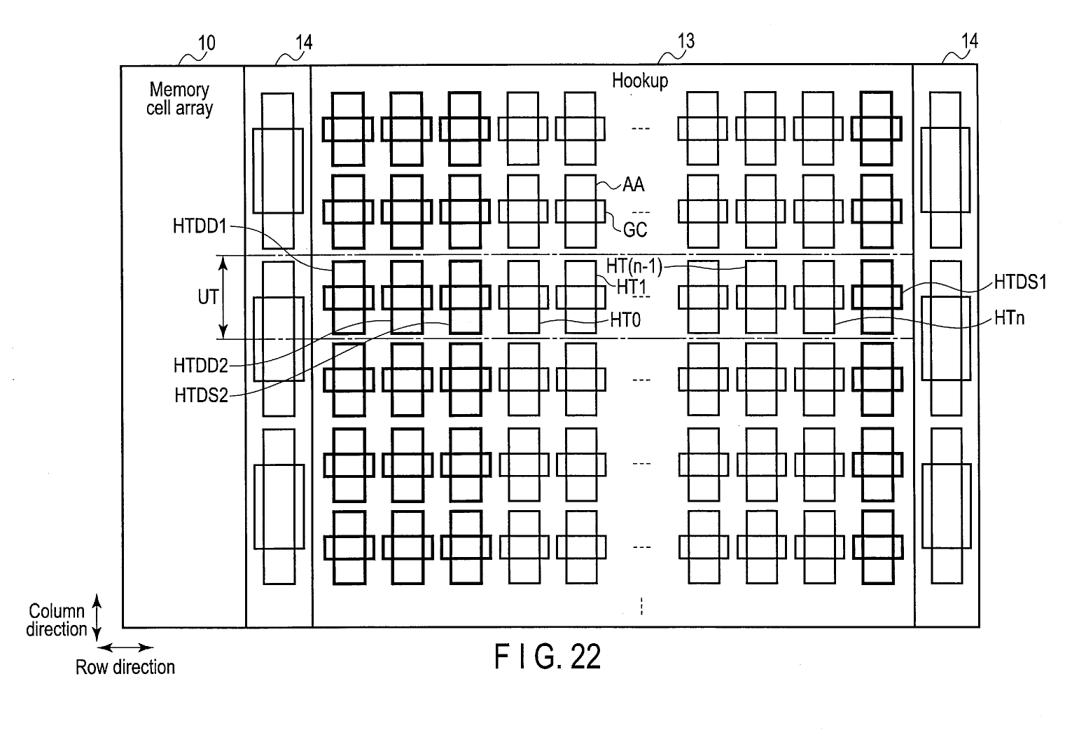

The fourteenth embodiment relates to a layout in which dummy hookup transistors are unevenly arranged at the two ends of a unit UT. FIG. 22 is a layout diagram of a hookup circuit 13 according to the fourteenth embodiment.

A group of hookup transistors included in one unit UT is aligned on one row in the row direction. Three of the four dummy hookup transistors are arranged at the left end of the unit UT, while the remaining one is arranged at the right end of the unit UT. Referring to FIG. 22, for example, dummy hookup transistors HTDD1, HTDD2, and HTDS2 are arranged at the left end of the unit UT, while dummy hookup transistor HTDS1 is arranged at the right end of the unit UT.

Hookup transistors HT0 and HT1 are arranged near the dummy hookup transistors HTDD1, HTDD2, and HTDS2, while hookup transistors HT(n−1) and HTn are arranged near the dummy hookup transistor HTDS1. With this arrangement, variations in characteristics of hookup transistors HT0 to HTn can be reduced by arranging hookup transistors HT0, HT1, Ht(n−1), and HTn at positions under environments with relatively large differences from that of the center of the hookup circuit 13.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell array including memory strings, each of the memory strings including a first select transistor, a first dummy cell, memory cells, a second dummy cell, and a second select transistor connected in series, the first dummy cell being arranged between the first select transistor and the memory cells, the second dummy cell being arranged between the memory cells and the second select transistor;
word lines connected to the memory cells;
a first dummy word line connected to the first dummy cell;
a second dummy word line connected to the second dummy cell; and
a row decoder configured to drive the word lines, the first dummy word line, and the second dummy word line,
the row decoder comprising first hookup transistors connected to the word lines, a first dummy hookup transistor connected to the first dummy word line, and a second dummy hookup transistor connected to the second dummy word line,
wherein a group of hookup transistors formed by the first hookup transistors, the first dummy hookup transistor, and the second dummy hookup transistor is aligned on either of one row and rows, and
the first dummy hookup transistor and the second dummy hookup transistor are arranged at least at one end of the group of hookup transistors.

2. The device of claim 1, wherein the first dummy hookup transistor and the second dummy hookup transistor are arranged at two ends of the group of hookup transistors.

3. The device of claim 1, further comprising a third dummy hookup transistor which is not connected to the memory string,
wherein the first dummy hookup transistor, the second dummy hookup transistor, and the third dummy hookup transistor are arranged at two ends of the group of hookup transistors.

4. The device of claim 1, further comprising:
a first select transistor connected in series with the first dummy cell;
a second select transistor connected in series with the second dummy cell;
a first select gate line and a second select gate line connected to the first select transistor and the second select transistor, respectively; and
a second hookup transistor and a third hookup transistor connected to the first select gate line and the second select gate line, respectively,
wherein the second hookup transistor and the third hookup transistor are arranged inside the dummy hookup transistors of the group of hookup transistors.

5. The device of claim 1, further comprising a signal line commonly connected to gates of the first hookup transistors, the first dummy hookup transistor, and the second dummy hookup transistor.

6. The device of claim 1, wherein at least one of hookup transistors for memory cells adjacent to the first dummy cell and the second dummy cell are arranged adjacent to the first dummy hookup transistor and the second dummy hookup transistor.

7. The device of claim 1, further comprising a guard ring arranged between the memory cell array and the group of hookup transistors.

8. The device of claim 1, wherein the memory cell includes a charge storage layer and a control gate electrode.

9. A semiconductor memory device comprising:
a memory cell array including memory strings, each of the memory strings including a first select transistor, first dummy cells, memory cells, second dummy cells connected in series and a second select transistor, the first dummy cells being arranged between the first select transistor and the memory cells, the second dummy cells being arranged between the memory cells and the second select transistor;
word lines connected to the memory cells;
first dummy word lines connected to the first dummy cells;
second dummy word lines connected to the second dummy cells; and
a row decoder configured to drive the word lines, the first dummy word lines, and the second dummy word lines,
the row decoder comprising first hookup transistors connected to the word lines, first dummy hookup transistors connected to the first dummy word lines, and second dummy hookup transistors connected to the second dummy word lines,
wherein a group of hookup transistors formed by the first hookup transistors, the first dummy hookup transistors, and the second dummy hookup transistors is aligned on either of one row and rows, and
the first dummy hookup transistors and the second dummy hookup transistors are arranged at least at one end of the group of hookup transistors.

10. The device of claim 9, wherein the first dummy hookup transistors and the second dummy hookup transistors are arranged at two ends of the group of hookup transistors.

11. The device of claim 9, wherein the first dummy hookup transistors and the second dummy hookup transistors are evenly arranged at two ends of the group of hookup transistors.

12. The device of claim 9, wherein larger numbers of first dummy hookup transistors and second dummy hookup transistors are arranged on a side closer to the memory cell array than on a side farther from the memory cell array.

13. The device of claim 9, further comprising a third dummy hookup transistor which is not connected to the memory string,
wherein the first dummy hookup transistors, the second dummy hookup transistors, and the third dummy hookup transistor are arranged at two ends of the group of hookup transistors.

14. The device of claim 9, further comprising:
a first select transistor connected in series with the first dummy cells;
a second select transistor connected in series with the second dummy cells;
a first select gate line and a second select gate line connected to the first select transistor and the second select transistor, respectively; and
a second hookup transistor and a third hookup transistor connected to the first select gate line and the second select gate line, respectively,
wherein the second hookup transistor and the third hookup transistor are arranged inside the dummy hookup transistors of the group of hookup transistors.

15. The device of claim 9, further comprising a signal line commonly connected to gates of the first hookup transistors, the first dummy hookup transistors, and the second dummy hookup transistors.

16. The device of claim 9, wherein at least one of hookup transistors for memory cells adjacent to the first dummy cell and the second dummy cell are arranged adjacent to the first dummy hookup transistor and the second dummy hookup transistor.

17. The device of claim 9, further comprising a guard ring arranged between the memory cell array and the group of hookup transistors.

18. The device of claim 9, wherein the memory cell includes a charge storage layer and a control gate electrode.

19. A semiconductor memory device comprising:
a memory cell array including memory strings, each of the memory strings including a first select transistor, a first dummy cell, memory cells, a second dummy cell, and a second select transistor connected in series, the first dummy cell being arranged between the first select transistor and the memory cells, the second dummy cell being arranged between the memory cells and the second select transistor;
word lines connected to the memory cells;
a first dummy word line connected to the first dummy cell;
a second dummy word line connected to the second dummy cell; and
a row decoder configured to drive the word lines, the first dummy word line, and the second dummy word line,
the row decoder comprising first hookup transistors connected to the word lines, a first dummy hookup transistor connected to the first dummy word line, and a second dummy hookup transistor connected to the second dummy word line,
wherein a group of hookup transistors formed by the first hookup transistors, the first dummy hookup transistor, and the second dummy hookup transistor is aligned on either of one row and rows,
the first dummy hookup transistor and the second dummy hookup transistor are arranged at least at one end of the group of hookup transistors, and
second hookup transistors, which have a high resistance against a surrounding environment, of the first hookup transistors are arranged adjacent to the first dummy hookup transistor and the second dummy hookup transistor.

20. The device of claim 19, wherein the second hookup transistors comprise a hookup transistor connected to a word line adjacent to the first dummy word line and a hookup transistor connected to a word line adjacent to the second dummy word line.
